(19) United States
(12) Patent Application Publication
(10) Pub. No.: US 2026/0190431 A1
(43) Pub. Date: Jul. 2, 2026

(54) SEMICONDUCTOR DEVICE AND METHOD FOR PREPARING THE SAME

(71) Applicant: NANYA TECHNOLOGY CORPORATION, NEW TAIPEI CITY (TW)

(72) Inventor: TSE-YAO HUANG, NEW TAIPEI CITY (TW)

(21) Appl. No.: 19/004,572

(22) Filed: Dec. 30, 2024

(51) Int. Cl. H10D 64/66; H10B 12/00; H10D 64/27

(52) U.S. Cl. CPC H10D 64/664; H10B 12/30; H10B 12/50; H10D 64/513; H10D 64/663; H10B 12/05

(57) ABSTRACT

The present disclosure provides a semiconductor device including a source/drain structure, a dielectric layer, first contact structures, a polysilicon stack, and a second contact structure. The source/drain structure is disposed over a semiconductor substrate. The dielectric layer is disposed over the source/drain structure. The first contact structures penetrates through the dielectric layer and the source/drain structure. The second contact structure is disposed over the polysilicon stack. The polysilicon stack and the second contact structure are disposed between two of the plurality of first contact structures. Each of the first contact structures includes a first liner and a first conductive layer surrounding by the first liner.

### TECHNICAL FIELD

The present disclosure relates to a semiconductor device and a method for preparing the same, and more particularly, to a semiconductor device with two types of contacts and a method for preparing the same.

### DISCUSSION OF THE BACKGROUND

Semiconductor devices are essential for many modern applications. With the advancement of electronic technology, semiconductor devices are becoming smaller in size while providing greater functionality and including greater amounts of integrated circuitry. Due to the miniaturized scale of semiconductor devices, various types and dimensions of semiconductor devices providing different functionalities are integrated and packaged into a single module. Furthermore, numerous manufacturing operations are implemented for integration of various types of semiconductor devices.

However, the manufacturing and integration of semiconductor devices involve many complicated steps and operations. Integration in semiconductor devices becomes increasingly complicated. An increase in complexity of manufacturing and integration of the semiconductor device may cause deficiencies. Accordingly, there is a continuous need to improve the manufacturing process of semiconductor devices so that the problems can be addressed.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

In one embodiment of the present disclosure, a semiconductor device is provided. The semiconductor device includes a source/drain structure, a dielectric layer, first contact structures, a polysilicon stack, and a second contact structure. The source/drain structure is disposed over a semiconductor substrate. The dielectric layer is disposed over the source/drain structure. The first contact structures penetrates through the dielectric layer and the source/drain structure. The second contact structure is disposed over the polysilicon stack. The polysilicon stack and the second contact structure are disposed between two of the plurality of first contact structures. Each of the first contact structures includes a first liner and a first conductive layer surrounding by the first liner

In another embodiment of the present disclosure, a method for preparing a semiconductor device is provided. The method includes: forming a source/drain structure over a semiconductor substrate; forming a dielectric layer over the source/drain structure; forming a plurality of first contact structures penetrating through the dielectric layer and the source/drain structure; and forming a second contact structure between two of the plurality of first contact structures, wherein the second contact structure is formed over the source/drain structure. The step of forming the plurality of first contact structures penetrating through the dielectric layer and the source/drain structure includes: performing a first etching process to form a plurality of first openings penetrating through the dielectric layer and the source/drain structure and extending into the semiconductor substrate; forming a first liner covering a sidewall and a bottom surface of each of the first openings; forming a second liner over the first liner; and filling a remaining portion of the first openings with a first conductive layer after the second liner is formed. The first liner and the second liner are made of different materials.

In another embodiment of the present disclosure, a semiconductor device is provided. The semiconductor device includes a semiconductor substrate, a source/drain structure, a dielectric layer, a first contact structure, a polysilicon stack, and a second contact structure. The semiconductor substrate includes an array area and a periphery area. The dielectric layer is disposed over the source/drain structure. The first contact structure is disposed over the periphery area and penetrates through the dielectric layer. The first contact structure includes a first liner and a first conductive layer. The first liner includes tantalum, tantalum nitride, or the combination thereof. The first conductive layer is disposed over the first liner and includes Cu.

In yet another embodiment of the present disclosure, a method for preparing a semiconductor device is provided. The method includes: forming a source/drain structure over a semiconductor substrate, wherein the semiconductor substrate comprises an array area and a periphery area; forming a dielectric layer over the source/drain structure; forming a first contact structure in the periphery area, penetrating through the dielectric layer; forming a polysilicon stack in the array area and over the source/drain structure; and forming a second contact structure over the polysilicon stack. The step of forming the first contact structure in the periphery area, penetrating through the dielectric layer includes: performing a first etching process to form a first opening penetrating through the dielectric layer; forming a first liner covering a sidewall and a bottom surface of the first opening; forming a second liner over the first liner, wherein the first liner and the second liner are made of different materials; and filling a remaining portion of the first opening with a first conductive layer after the second liner is formed.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a cross-sectional view illustrating a semiconductor device, in accordance with some embodiments.

FIG. 2 is a cross-sectional view illustrating a semiconductor device, in accordance with some embodiments.

FIG. 3 is a cross-sectional view illustrating a semiconductor device, in accordance with some embodiments.

FIG. 4 illustrates an intermediated stage of forming the semiconductor device, in accordance with some embodiments.

FIG. 5 illustrates an intermediated stage of forming the semiconductor device, in accordance with some embodiments.

FIG. 6 illustrates an intermediated stage of forming the semiconductor device, in accordance with some embodiments.

FIG. 7 illustrates an intermediated stage of forming the semiconductor device, in accordance with some embodiments.

FIG. 8 illustrates an intermediated stage of forming the semiconductor device, in accordance with some embodiments.

FIG. 9 illustrates an intermediated stage of forming the semiconductor device, in accordance with some embodiments.

FIG. 10 illustrates an intermediated stage of forming the semiconductor device, in accordance with some embodiments.

FIG. 11 illustrates an intermediated stage of forming the semiconductor device, in accordance with some embodiments.

FIG. 12 illustrates an intermediated stage of forming the semiconductor device, in accordance with some embodiments.

FIG. 13 illustrates an intermediated stage of forming the semiconductor device, in accordance with some embodiments.

FIG. 14 illustrates an intermediated stage of forming the semiconductor device, in accordance with some embodiments.

FIG. 15 illustrates an intermediated stage of forming the semiconductor device, in accordance with some embodiments.

FIG. 16 illustrates an intermediated stage of forming the semiconductor device, in accordance with some embodiments.

FIG. 17 illustrates an intermediated stage of forming the semiconductor device, in accordance with other embodiments.

FIG. 18 illustrates an intermediated stage of forming the semiconductor device, in accordance with other embodiments.

FIG. 19 illustrates an intermediated stage of forming the semiconductor device, in accordance with other embodiments.

FIG. 20 illustrates an intermediated stage of forming the semiconductor device, in accordance with other embodiments.

FIG. 21 is a flow chart of a method for preparing a semiconductor device, in accordance to some embodiments.

FIG. 22 is a flow chart of a method for preparing a semiconductor device, in accordance to some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

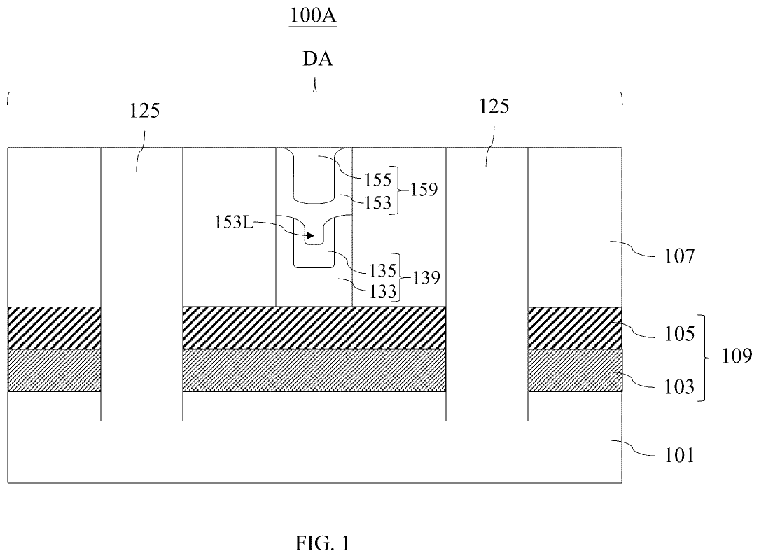

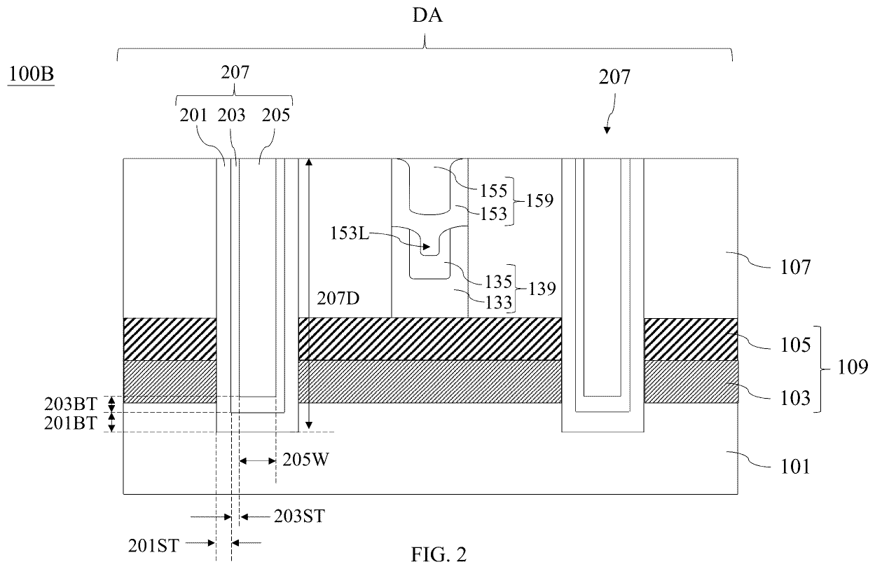

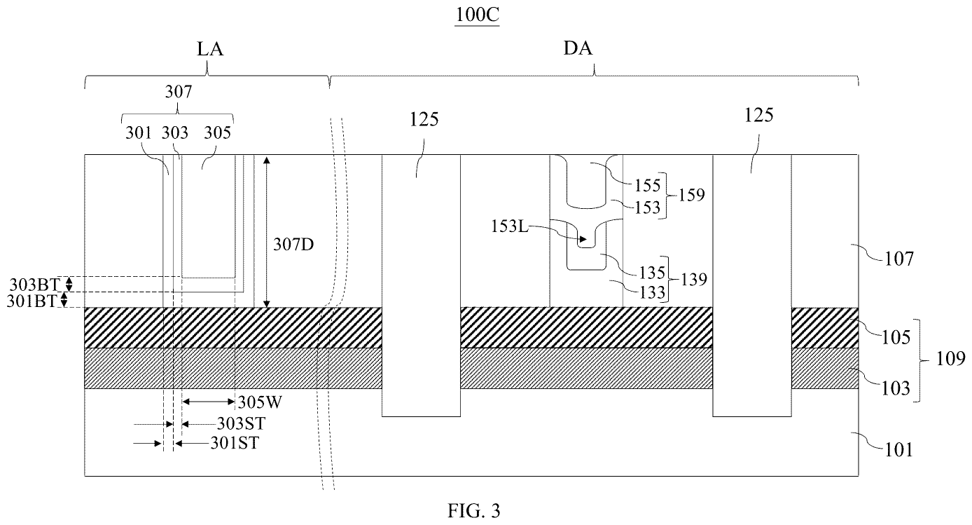

FIG. 1, FIG. 2, and FIG. 3 are cross-sectional views illustrating semiconductor devices 100A, 100B, and 100C, respectively, in accordance with some embodiments. In some embodiments, the semiconductor device 100A, the semiconductor device 100B, the semiconductor device 100C, or the combination thereof is part of dynamic random access memory (DRAM).

The entire DRAM includes many electrical components. These electrical components are disposed on an array area DA (also referred to as dense area) and a periphery area LA (also referred to as loose area) of the semiconductor substrate 101. The semiconductor device 100A and the semiconductor device 100B are disposed on the array area DA. A portion of the semiconductor device 100C is disposed in the periphery area LA, and another portion of the semiconductor device 100C is disposed in the array area DA.

The semiconductor device 100A, the semiconductor device 100B, and the semiconductor device 100C include a source/drain structure 109 disposed over a semiconductor substrate 101, and a dielectric layer 107 disposed over the source/drain structure 109. The source/drain structure 109 includes an epitaxial layer 103 and a silicide layer 105 disposed over the epitaxial layer 103. In some embodiments, the epitaxial layer 103 is entirely covered by the silicide layer 105, such that the epitaxial layer 103 is separated from the dielectric layer 107 by the silicide layer 105. In some embodiments, the epitaxial layer 103 includes silicon (Si), and the silicide layer 105 includes cobalt silicide (CoSiₓ).

The semiconductor device 100A and the semiconductor device 100C further include gate structures 125 penetrating through the dielectric layer 107, the silicide layer 105 and the epitaxial layer 103 toward the semiconductor substrate 101. The gate structures 125 are disposed in the array area DA. In some embodiments, the gate structures 125 are recess gate structures. The gate structures 125 extend into the semiconductor substrate 101, and bottom surfaces of the gate structure 125 are within the semiconductor substrate 101.

The semiconductor device 100A, the semiconductor device 100B, and the semiconductor 100C further include a polysilicon stack 139 and a contact structure 159 disposed directly over the polysilicon stack 139. The polysilicon stack 139 and the contact structure 159 are disposed in the array area DA. The polysilicon stack 139 is disposed in the dielectric layer 107 and over the source/drain structure 109. In some embodiments, the polysilicon stack 139 and the contact structure 159 are surrounded by the dielectric layer 107. In the semiconductor device 100A and the semiconductor device 100C, the polysilicon stack 139 and the contact structure 159 are disposed between the gate structures 125.

The polysilicon stack 139 includes a first polysilicon layer 133 and a second polysilicon layer 135 disposed over and surrounded by the first polysilicon layer 133. In some embodiments, the second polysilicon layer 135 is separated from the dielectric layer 107 by the first polysilicon layer 133. In some embodiments, the first polysilicon layer 133 is undoped, and the second polysilicon layer 135 is doped. In some embodiments, the second polysilicon layer 135 is doped with arsenic (As), boron (B), or phosphorous (P).

The first polysilicon layer 133 has a U-shape profile from the cross-sectional view. The first polysilicon layer 133 is in contact with sidewalls and a bottom surface of the second polysilicon layer 135. In other words, the first polysilicon layer 133 has a recess from the cross-sectional view, and the second polysilicon layer 135 is filled in the recess. A top portion of the first polysilicon layer 133 and a top portion of the second polysilicon layer 135 are in contact with the contact structure 159. The second polysilicon layer 135 is enclosed by the first polysilicon layer 133 and the contact structure 159.

The contact structure 159 includes the barrier layer 153 and the conductive layer 155. The conductive layer 155 is disposed over and surrounded by the barrier layer 153. In some embodiments, the barrier layer 153 includes titanium (Ti), titanium nitride (TiN), or a combination thereof. In some embodiments, the conductive layer 155 includes tungsten (W). In some embodiments, the conductive layer 155 is separated from the polysilicon stack 139 by the barrier layer 153. In some embodiments, the barrier layer 153 has the lower portion 153L surrounded by the polysilicon stack 139. In other words, the second polysilicon layer 135 has a recess from the cross-sectional vies, and the lower portion 153L is disposed in the recess of the second polysilicon layer 135. In some embodiments, the contact structure 159 is electrically connected to the source/drain structure 109 through the polysilicon stack 139.

The semiconductor device 100B further includes vontact structures 207. The contact structure 207 includes a first liner 201, a second liner 203, and a conductor layer 205. The first liner 201 is disposed over the semiconductor substrate 101 and in contact with the semiconductor substrate 101, the epitaxial layer 103, the silicide layer 105, and the dielectric layer 107. The second liner 203 is disposed over and surrounded by the first liner 201. The conductor layer 205 is disposed over and surrounded by the second liner 203.

The first liner 201 and the second liner 205 have U-shaped profile from the cross-sectional view. In some embodiments, a thickness 201BT of bottom portion of the first liner 201 is greater than or equal to a thickness 201ST of sidewall portion of the first liner 201. In some embodiments, a thickness 203BT of bottom portion of the second liner 203 is greater than or equal to a thickness 203ST of sidewall portion of the second liner 203. In some embodiments, the thickness 201BT of bottom portion of the first liner 201 is greater than or equal to the thickness 203BT of bottom portion of the second liner 203. In some embodiments, the thickness 201ST of sidewall portion of the first liner 201 is greater than or equal to the thickness 203ST of sidewall portion of the second liner 203. In some embodiments, a width 205W of the conductive layer 205 is greater than the thickness 203ST of sidewall portion of the second liner 203. In some embodiments, the width 205W of the conductive layer 205 is greater than the thickness 201ST of sidewall portion of the first liner 201.

In some embodiments, the first liner 201 and the second liner 203 are collectively referred to as a barrier layer. In some embodiments, the first liner 201 can be omitted.

The contact structures 207 are disposed in the array area DA. In some embodiments, the contact structure 159 and the polysilicon stack 139 are disposed between the contact structures 207 as shown in FIG. 2.

The semiconductor device 100C further includes contact structures 307. The contact structure 307 includes a first liner 301, a second liner 303, and a conductor layer 305. The first liner 301 is disposed over the source/drain structure 109 and in contact with the source/drain structure 109 and the dielectric layer 107. The second liner 303 is disposed over and surrounded by the first liner 301. The conductor layer 305 is disposed over and surrounded by the second liner 303. The contact structures 307 are disposed in the periphery area LA as shown in FIG. 3.

In some embodiments, the first liner 301 and the second liner 303 are collectively referred to as a barrier layer. In some embodiments, the first liner 301 can be omitted.

In some embodiments, the first liner 301 and the first liner 201 include the same material. In some embodiments, the second liner 303 and the second liner 203 include the same material. In some embodiments, the conductive layer 305 and the conductive layer 205 include the same material.

In some embodiments, the first liner 301 and the first liner 201 are made of tantalum (Ta), tantalum nitride (TaN), or the combination thereof. In some embodiments, the second liner 303 and the second liner 203 are made of CuMn. In some embodiments, the conductive layer 305 and the conductive layer 205 are made of Cu.

The first liner 301 and the second liner 305 have U-shaped profile from the cross-sectional view. In some embodiments, a thickness 301BT of bottom portion of the first liner 301 is greater than or equal to a thickness 301ST of sidewall portion of the first liner 301. In some embodiments, a thickness 303BT of bottom portion of the second liner 303 is greater than or equal to a thickness 303ST of sidewall portion of the second liner 303. In some embodiments, the thickness 301BT of bottom portion of the first liner 301 is greater than or equal to the thickness 303BT of bottom portion of the second liner 303. In some embodiments, the thickness 301ST of sidewall portion of the first liner 301 is greater than or equal to the thickness 303ST of sidewall portion of the second liner 303. In some embodiments, a width 305W of the conductive layer 305 is greater than the thickness 303ST of sidewall portion of the second liner 303. In some embodiments, the width 305W of the conductive layer 305 is greater than the thickness 301ST of sidewall portion of the first liner 301.

In some embodiment, the width 205W of the conductive layer 205 is less than the width 305W of the conductive layer 305. In some embodiment, the thickness 201BT of sidewall portion of the first liner 201 is less than the thickness 301BT of sidewall portion of the first liner 301, and the thickness 203BT of sidewall portion of the second liner 203 is less than the thickness 303BT of sidewall portion of the second liner 303. In some embodiments, a depth 207D of the contact structures 207 is greater than a depth 307D of the contact structures 307.

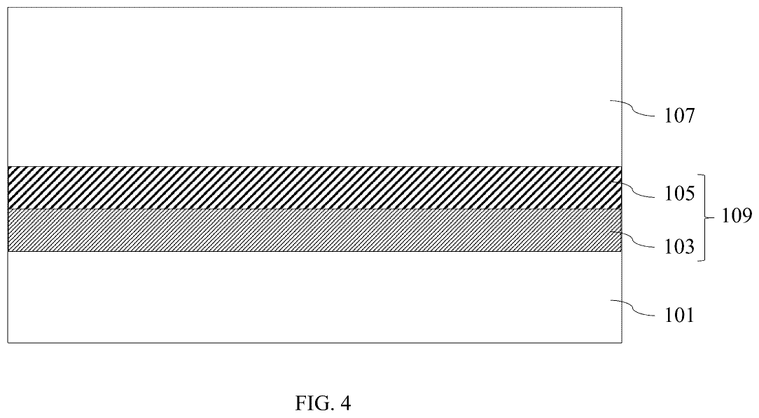

Reference is made to FIG. 4 to FIG. 16. FIG. 4 to FIG. 16 illustrate intermediated stages of forming the semiconductor device 100B, in accordance with some embodiments of present disclosure.

As shown in FIG. 4, a source/drain structure 109 including an epitaxial layer 103 and a silicide layer 105 is formed over a semiconductor substrate 101.

In some embodiments, the semiconductor substrate 101 is a semiconductor wafer such as a silicon wafer. Alternatively or additionally, the semiconductor substrate 101 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP.

The source/drain structure 109 may be a raised (or elevated) source/drain structure formed over the semiconductor substrate 101. In some embodiments, the epitaxial layer 103 of the source/drain structure 109 includes silicon, and the silicide layer 105 of the source/drain structure 109 includes cobalt silicide (CoSiₓ). In some embodiments, the epitaxial layer 103 is formed by an epitaxial growth method, which may include metal-organic chemical vapor deposition (MOCVD), vapor-phase epitaxy (VPE), molecular-beam epitaxy (MPE), liquid-phase epitaxy (LPE), or another suitable process. Moreover, in some embodiments, the silicide layer 105 is formed by a process that includes depositing a metal layer, such as cobalt (Co), and annealing the metal layer such that the metal layer can react with the epitaxial layer 103 to form the silicide layer 105.

After the source/drain structure 109 is formed, a dielectric layer 107 is formed over the silicide layer 105 of the source/drain structure 109, in accordance with some embodiments. In some embodiments, the dielectric layer 107 includes silicon oxide, silicon nitride, silicon oxynitride, a dielectric material with low dielectric constant (low-k), or a combination thereof. The dielectric layer 107 may be formed by a deposition process, such as a chemical vapor deposition (CVD) process, a physical vapor deposition (PVD) process, an atomic layer deposition (ALD) process, or another suitable process.

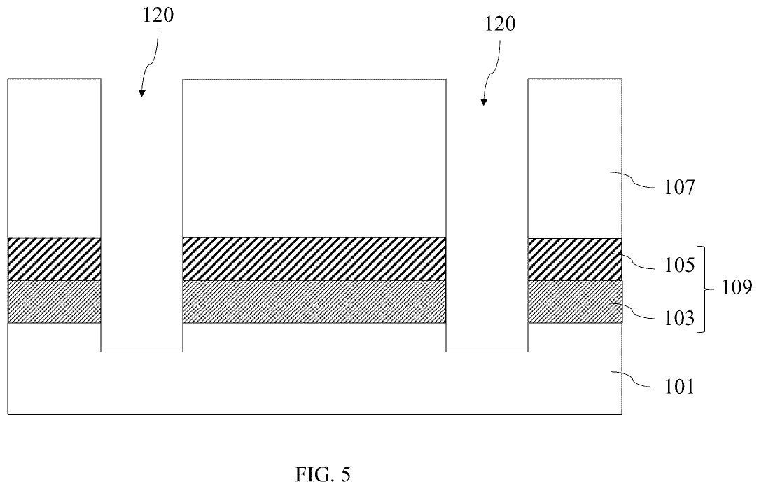

As shown in FIG. 5, openings 120 are formed penetrating through the dielectric layer 107 and the source/drain structure 109. In some embodiments, the openings 120 extend into an upper portion of the semiconductor substrate 101, such that the bottom surfaces of the openings 120 are located within the semiconductor substrate 101. The openings 120 may be formed by an etching process, and the locations of the openings 120 may be defined by a patterned mask (not shown) formed over the dielectric layer 107. The etching process may include a dry etching process, a wet etching process, or a combination thereof. After the etching process, the patterned mask over the dielectric layer 107 is removed.

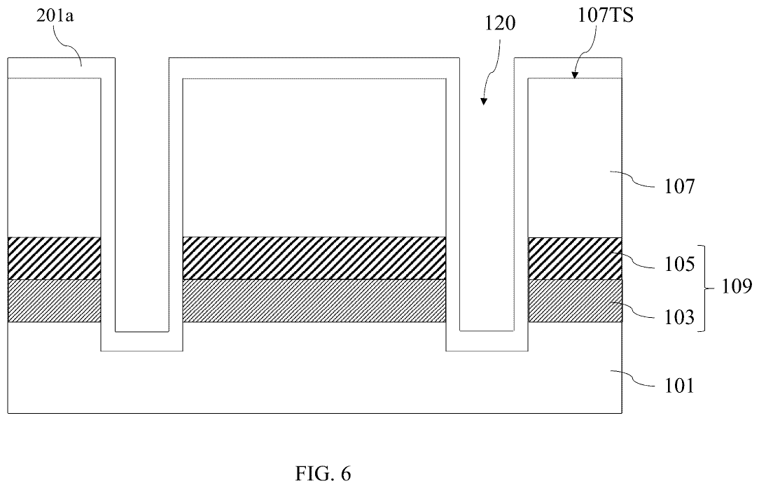

As shown in FIG. 6, a liner material 201a is formed in and lining the openings 120 and over a top surface 107TS of the dielectric layer 107. In some embodiments, the liner material 201a is made of Ta, and is formed by a deposition process, such as a CVD process, an ALD process, a PVD process, or a combination thereof. In other embodiments, the liner material 201a is made of TaN. In various embodiments, the liner material 201a is made of Ta and TaN.

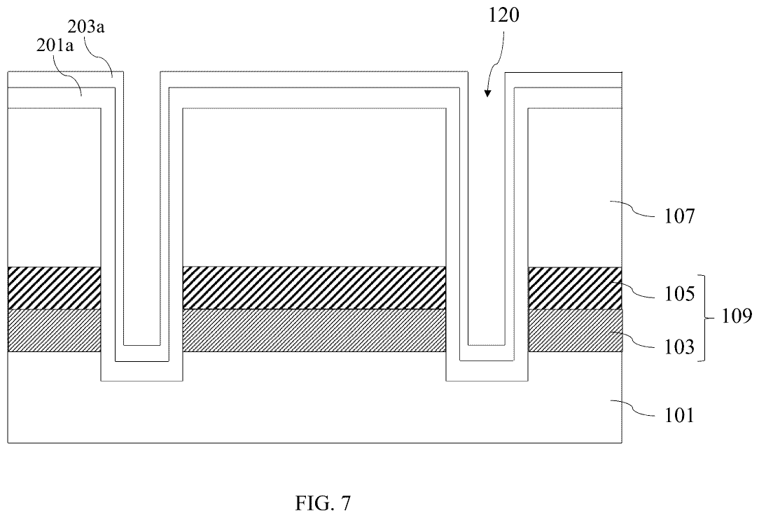

As shown in FIG. 7, a liner material 203a is formed in the openings 120 and over the liner material 201a. In some embodiments, the liner material 203a is made of CuMn, and is formed by a deposition process, such as a CVD process, an ALD process, a PVD process, or a combination thereof.

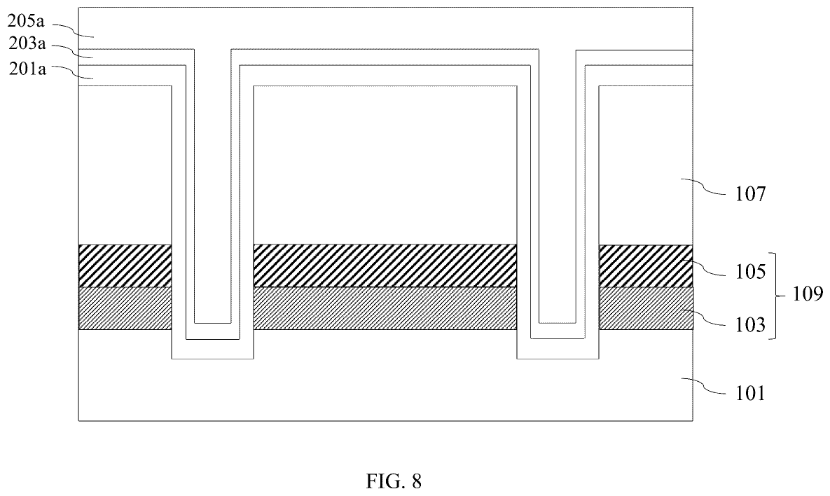

As shown in FIG. 8, a conductive material 205a is formed over the liner material 203a and to fill the openings 120. The conductive material 205a is separated from the dielectric layer 107, source/drain structure 109, and the semiconductor substrate 101 by the liner material 201a and the liner material 203a. In some embodiments, the conductive material 205a is made of Cu, and is formed by a deposition process, such as a CVD process, an ALD process, a PVD process, a sputtering process, a plating process, or a combination thereof.

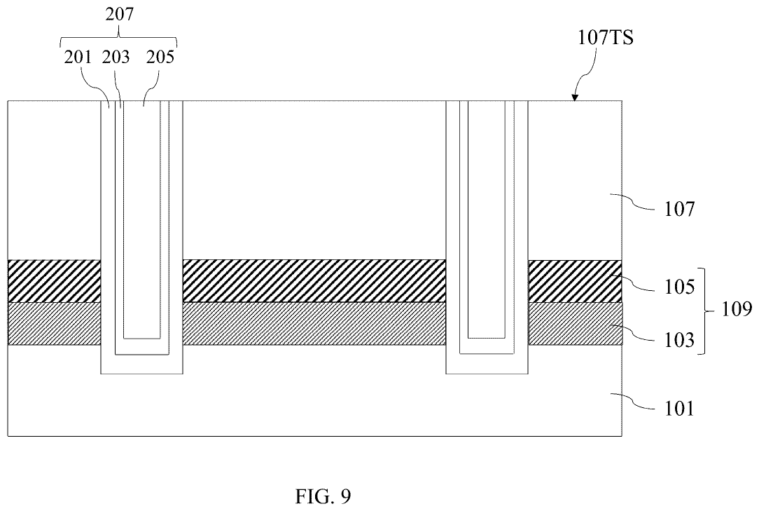

As shown in FIG. 9, a planarization process, such as a CMP process, is performed on the liner material 201a, the liner material 203a, and the conductive material 205a to remove any excess material over the top surface 107TS of the dielectric layer 107, such that the remaining liner material 201a, the remaining liner material 203a, and the remaining conductive material 205a become the first liner 201, the second liner 203, and the conductive layer 205, respectively. Therefore, the conductive structures 207 including the first liner 201, the second liner 203, and the conductive layer 205 are obtained.

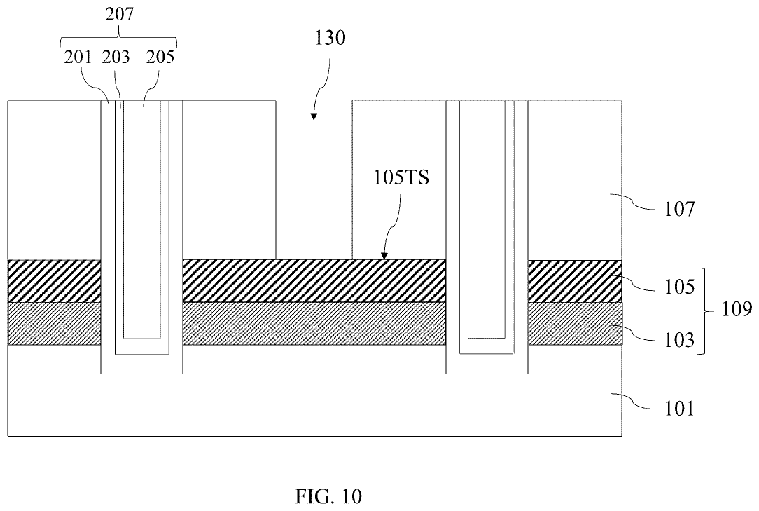

As shown in FIG. 10, an opening 130 is formed penetrating through the dielectric layer 107. In some embodiments, the opening 130 is located between the contact structures 207, and a top surface 105T of the silicide layer 105 is partially exposed by the opening 130. The opening 130 is formed by an etching process, and the location of the opening 130 may be defined by a patterned mask (not shown) formed over the dielectric layer 107 and the contact structures 207. In some embodiments, the etching process includes a dry etching process, a wet etching process, or a combination thereof. After the etching process, the patterned mask is be removed.

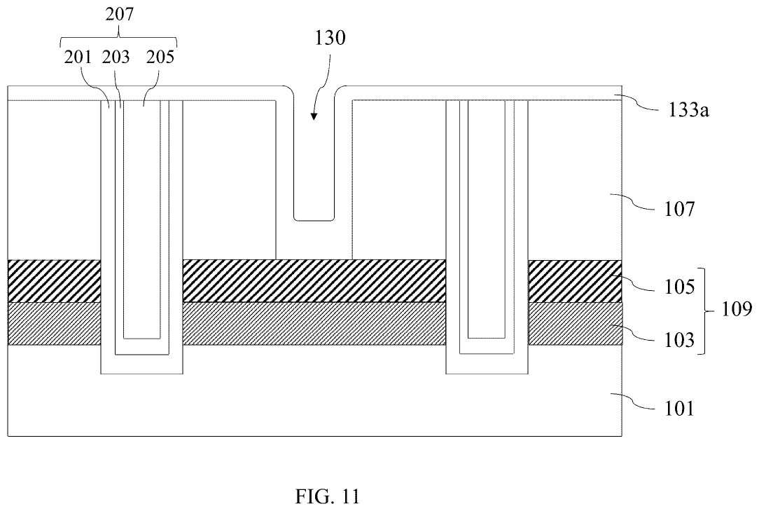

As shown in FIG. 11, a polysilicon material 133a is formed in the opening 130 and extending over the top surface 107TS of the dielectric layer 107. In some embodiments, the polysilicon material 133a is formed by a deposition process, such as a CVD process, a PVD process, an ALD process, or a combination thereof.

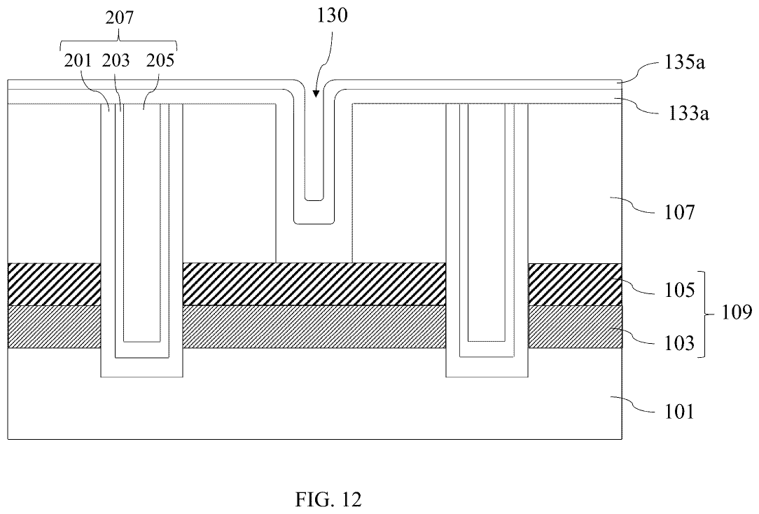

As shown in FIG. 12, a polysilicon material 135a is formed in the opening 130 and over the polysilicon material 133a. In some embodiments, the polysilicon material 135a is formed by a deposition process, such as a CVD process, a PVD process, an ALD process, or a combination thereof.

In some embodiments, the polysilicon material 133a is undoped, and the polysilicon material 135a is doped with arsenic (As), boron (B), or phosphorous (P). In some embodiments, the polysilicon material 135a is in-situ doped during the deposition process. In some embodiments, the polysilicon material 135a is not in-situ doped, and instead an implantation process is performed to dope the polysilicon material 135a.

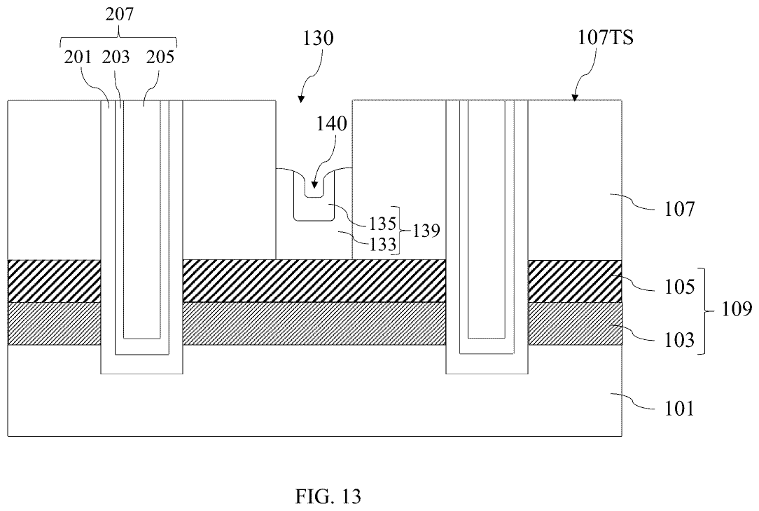

As shown in FIG. 13, an etch back process is performed on the polysilicon material 133a and the polysilicon material 135a to remove the portions of the polysilicon material 133a and the polysilicon material 135a over the top surface 107TS of the dielectric layer 107 and to remove the portions of the polysilicon material 133a and the polysilicon material 135a occupying the upper portion of the opening 130. As illustrated, the remaining portions of the polysilicon material 133a and the polysilicon material 135a form a polysilicon stack 139. More specifically, the remaining portion of the polysilicon material 133a becomes a first polysilicon layer 133, and the remaining portion of the polysilicon material 135a becomes a second polysilicon layer 135.

It should be noted that an opening 140 is formed over the second polysilicon layer 135. The opening 140 is a portion of the opening 130.

In some embodiments, the etch back process includes a dry etching process, a wet etching process, or a combination thereof. In addition, the polysilicon material 133a can be etched back before the deposition process for forming the polysilicon material 135a is performed.

It should be noted that although only two polysilicon layers (i.e., the first polysilicon layer 133 and the second polysilicon layer 135) are shown in the polysilicon stack 139, the polysilicon stack 139 may have more than two polysilicon layers. In some embodiments, the processes for forming the first polysilicon layer 133 and the second polysilicon layer 135 are repeated as a cycle to form more polysilicon layers over the second polysilicon layer 135. For example, a third polysilicon layer, which is undoped, is formed over the second polysilicon layer 135, and a fourth polysilicon layer, which is doped with arsenic, boron, or phosphorous, is formed over the third polysilicon layer.

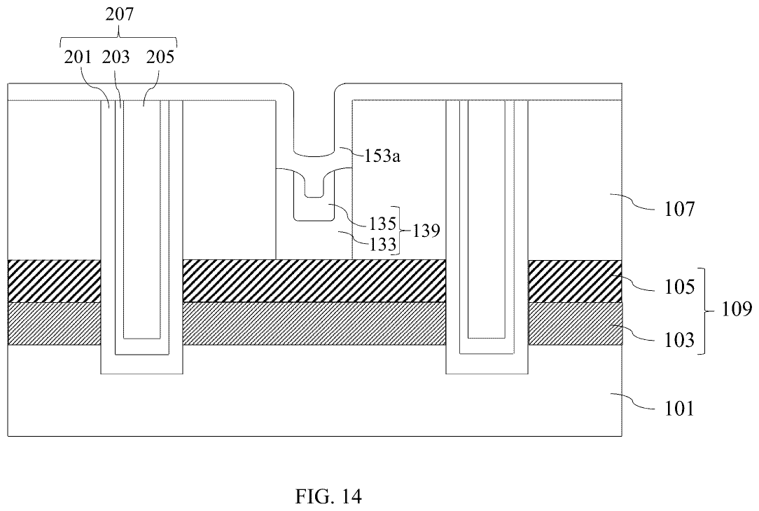

As shown in FIG. 14, a barrier material 153a is formed in the opening 130 and filled into the opening 140. The barrier material 153a is further formed over the polysilicon stack 139 and extends over the top surface 107TS of the dielectric layer 107. In some embodiments, the barrier material 153a includes titanium (Ti), titanium nitride (TiN), or a combination thereof. In some embodiments, the barrier material 153a is formed by a deposition process, such as a CVD process, a PVD process, an ALD process, or a combination thereof.

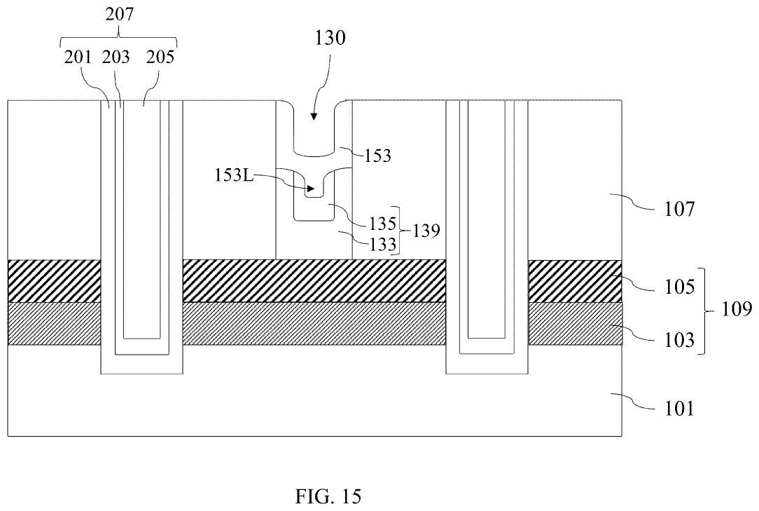

As shown in FIG. 15, an etching process is performed on the barrier material 153a to remove the excess portion of the barrier material 153a over the top surface TS of the dielectric layer 107. In some embodiments, the excess portion of the barrier material 153a is removed by an etch back process, or a planarization process (e.g., CMP, grinding, or the like). After the etching process, the remaining portion of the barrier material 153a becomes the barrier layer 153.

The portion of the barrier layer 153 disposed in the opening 140 becomes a lower portion 153L of the barrier layer 153. The lower portion 153L is surrounded by the second polysilicon layer 135. In some embodiments, the barrier layer 153 is in direct contact with the first polysilicon layer 133, the second polysilicon layer 135, and the dielectric layer 107.

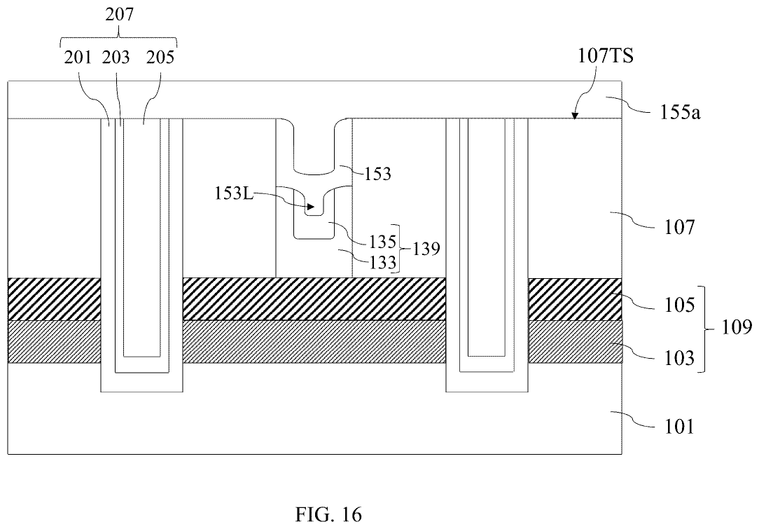

As shown in FIG. 16, the remaining portion of the opening 130 is filled by a conductive material 155a, and the conductive material 155a further extends over the top surface 107TS of the dielectric layer 107. In some embodiments, the conductive material 155a includes tungsten (W). In some embodiments, the conductive material 155a is formed by a deposition process, such as a CVD process, a PVD process, an ALD process, or a combination thereof.

Subsequently, a planarization process is performed on the conductive material 155a to remove the excess portion of the conductive material 155a over the top surface 107TS of the dielectric layer 107. After the planarization process, the remaining conductive material 155a becomes a conductive layer 155. A conductive structure 159 including the barrier layer 153 and the conductive layer 155 is formed over the polysilicon stack 139 and surrounded by the dielectric layer 107 as illustrated in FIG. 2.

In some embodiments, the planarization process may include a CMP process. After the conductive structure 159 is obtained, the semiconductor device 100B is obtained. Since the polysilicon stack 139 with an undoped polysilicon layer (i.e., the first polysilicon layer 133) and a doped polysilicon layer (i.e., the second polysilicon layer 135) over the undoped polysilicon layer is formed between the source/drain structure 109 and the contact structure 159, the contact resistance may be reduced. As a result, the device performance of the semiconductor device 100B may be enhanced.

Regarding the semiconductor device 100A, the intermediated stages of forming the semiconductor device 100A are similar to those of the semiconductor device 100B. Specifically, the intermediated stages of forming the semiconductor device 100B shown in FIG. 4, FIG. 5, and FIG. 10 to FIG. 16 are substantially the same as the intermediated stages of forming the semiconductor device 100A. After the process shown in FIG. 5, a except the intermediated stages shown in FIG. 6 to FIG. 9, gate structures 125 are formed in the openings 120. In some embodiments, the gate structures 125 are recessed gate structures of the DRAM. Each of the gate structures 125 includes a gate dielectric (not shown) and a gate electrode (not shown) disposed over and surrounded by the gate dielectric. Each of the gate dielectrics may include silicon oxide, silicon nitride, silicon oxynitride, a dielectric material with high dielectric constant (high-k), or a combination thereof, and each of the gate electrodes may include a conductive material such as aluminum (Al), copper (Cu), tungsten (W), titanium (Ti), tantalum (Ta), or may be a multi-layer structure including any combination of the above materials.

In some embodiments, the formation of the gate structures 125 includes depositing a gate dielectric material (not shown) lining the openings 120 and covering the top surface 107TS of the dielectric layer 107, depositing a gate electrode material (not shown) in the remaining portions of the openings 120 and over the top surface 107TS of the dielectric layer 107, and performing a planarization process on the gate dielectric material and the gate electrode material. In some embodiments, the deposition processes include CVD, PVD, ALD, or another suitable process. In some embodiments, the planarization process includes a CMP process, a grinding process, an etching process, or another suitable process.

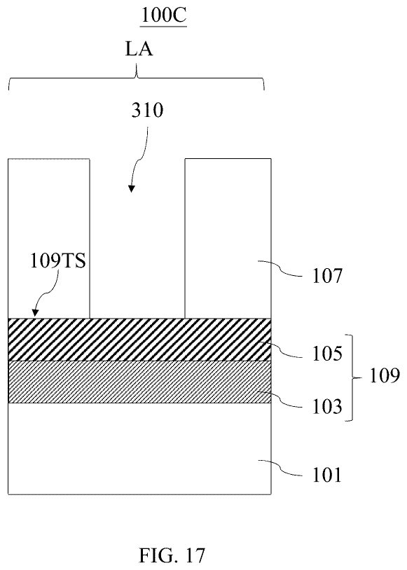

FIG. 17 to FIG. 20 illustrate intermediated stages of forming the contact structure 307 of the semiconductor device 100C according to some embodiments of the present disclosure. For the sake of brevity, FIG. 17 to FIG. 20 merely illustrate the periphery area LA of the semiconductor device 100C.

The formations of the semiconductor device 100C in the array area DA are substantially the same as the formation of the semiconductor device 100A. In some embodiments, the formation of the contact structure 307 shown in FIG. 17 to FIG. 22 is performed after the forming of the gate structures 125. In other embodiments, the formation of the contact structure 307 shown in FIG. 17 to FIG. 22 is performed before the forming of the gate structures 125. In various embodiments, the formation of the contact structure 307 shown in FIG. 17 to FIG. 22 is performed after the forming of the contact structure 159.

As shown in FIG. 17, an openings 310 is formed penetrating through the dielectric layer 107. In some embodiments, the opening 310 extends toward the semiconductor substrate 101, and the bottom surfaces of the opening 310 is substantially coplanar with the top surface 109TS of the source/drain structure 109. The opening 310 may be formed by an etching process, and the location of the opening 310 may be defined by a patterned mask (not shown) formed over the dielectric layer 107. The etching process may include a dry etching process, a wet etching process, or a combination thereof. After the etching process, the patterned mask over the dielectric layer 107 is removed.

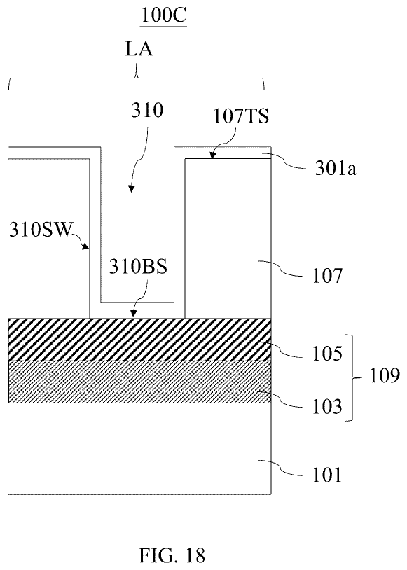

As shown in FIG. 18, a liner material 301a is formed in and lining the opening 310 and over a top surface 107TS of the dielectric layer 107. The liner material 301a covers a bottom surface 130BS and a sidewall 130SW of the opening 310. In some embodiments, the liner material 301a is made of Ta, and is formed by a deposition process, such as a CVD process, an ALD process, a PVD process, or a combination thereof. In other embodiments, the liner material 301a is made of TaN. In various embodiments, the liner material 301a is made of Ta and TaN.

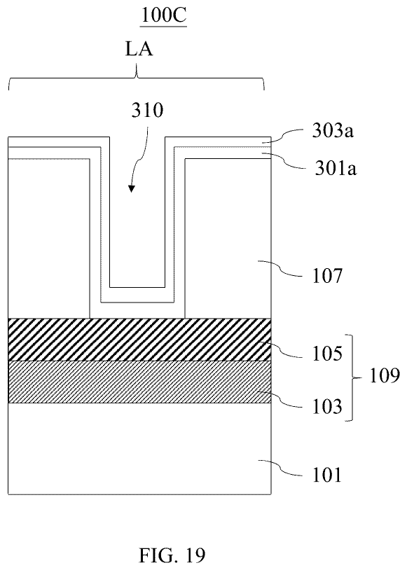

As shown in FIG. 19, a liner material 303a is formed in the openings 120 and over the liner material 301a. In some embodiments, the liner material 303a is made of CuMn, and is formed by a deposition process, such as a CVD process, an ALD process, a PVD process, or a combination thereof.

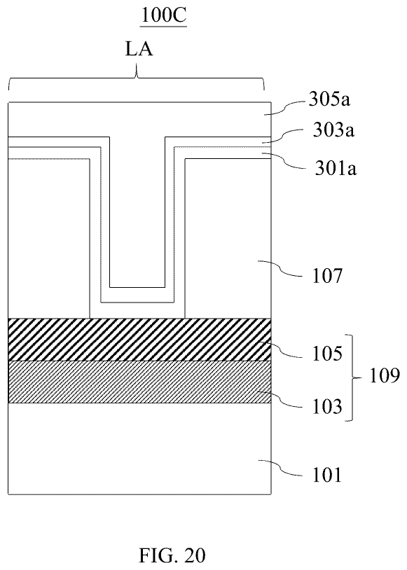

As shown in FIG. 20, a conductive material 305a is formed over the liner material 303a and to fill the opening 310. The conductive material 305a is separated from the dielectric layer 107 and source/drain structure 109 by the liner material 301a and the liner material 303a. In some embodiments, the conductive material 305a is made of Cu, and is formed by a deposition process, such as a CVD process, an ALD process, a PVD process, a sputtering process, a plating process, or a combination thereof.

Next, a planarization process, such as a CMP process, is performed on the liner material 301a, the liner material 303a, and the conductive material 305a to remove any excess material over the top surface 107TS of the dielectric layer 107, such that the remaining liner material 301a, the remaining liner material 303a, and the remaining conductive material 305a become the first liner 301, the second liner 303, and the conductive layer 305, respectively. Therefore, the conductive structures 307 including the first liner 301, the second liner 303, and the conductive layer 305 are obtained.

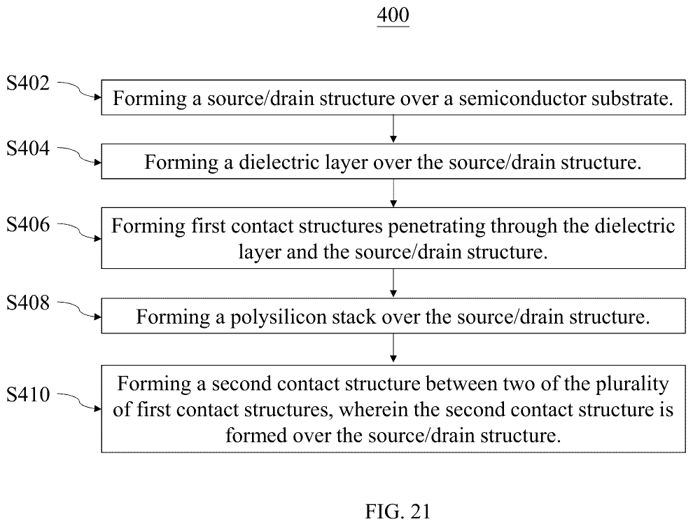

Reference is made to FIG. 21. FIG. 21 is a flow chart of a method 400 for preparing a semiconductor device 200B according to some embodiments of the present disclosure. The method 400 includes steps S402, S404, S406, S408, and S410. For the sake of brevity, the method 400 is described using the reference numerals shown in FIG. 1 to FIG. 20.

Please refer to FIG. 4. In step S402, a source/drain structure 109 is formed over the semiconductor substrate 101. In step S404, a dielectric layer 107 is formed over the source/drain structure 109.

In step S406, contact structures 207 are formed penetrating through the dielectric layer 107 and the source/drain structure 109. In some embodiments, the step S406 includes sub-steps which are respectively illustrated in FIG. 5 to FIG. 9.

In step S408, a polysilicon stack 139 is formed over the source/drain structure 109. In some embodiments, the step S408 includes sub-steps which are respectively illustrated in FIG. 10 to FIG. 13.

In step S410, a contact structure 159 is formed between two of the plurality of contact structures 207, in which the contact structure 159 is over the source/drain structure 109. In some embodiments, the step S410 includes sub-steps which are respectively illustrated in FIG. 14 to FIG. 16.

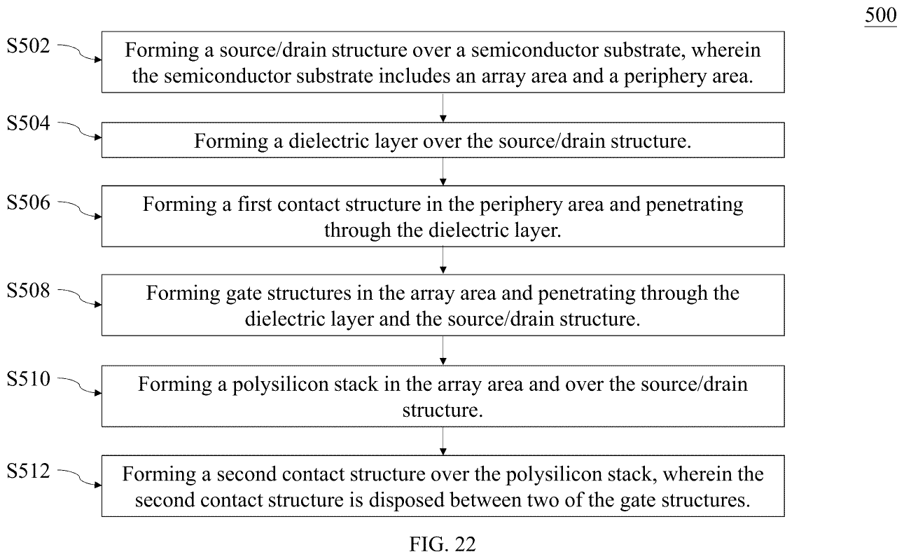

Reference is made to FIG. 22. FIG. 22 is a flow chart of a method 500 for preparing a semiconductor device 200C according to some embodiments of the present disclosure. The method 500 includes steps S502, S504, S506, S508, S510, and S512. For the sake of brevity, the method 500 is described using the reference numerals shown in FIG. 1 to FIG. 20.

In step S502, a source/drain 109 is formed over a semiconductor substrate 101, in which the semiconductor substrate 109 includes an array DA and a periphery area LA. In step S504, a dielectric layer 107 is formed over the source/drain structure 109.

In step S506, a contact structure 307 is formed in the periphery area LA and penetrating through the dielectric layer 107. In some embodiments, the step S506 includes sub-steps which are respectively illustrated in FIG. 17 to FIG. 20.

In step S508, gate structures 125 are formed in the array area DA and penetrating through the dielectric layer 107 and the source/drain structure 109.

In step S510, a polysilicon stack 139 is formed in the array area DA and over the source/drain structure 109. In some embodiments, the step S510 includes sub-steps which are respectively illustrated in FIG. 10 to FIG. 13.

In step S512, a contact structure 159 is formed over the polysilicon 139, in which the contact structure 159 is disposed between two of the gate structures 125. In some embodiments, the step S512 includes sub-steps which are respectively illustrated in FIG. 14 to FIG. 16.

In one embodiment of the present disclosure, a semiconductor device is provided. The semiconductor device includes a source/drain structure, a dielectric layer, first contact structures, a polysilicon stack, and a second contact structure. The source/drain structure is disposed over a semiconductor substrate. The dielectric layer is disposed over the source/drain structure. The first contact structures penetrates through the dielectric layer and the source/drain structure. The second contact structure is disposed over the polysilicon stack. The polysilicon stack and the second contact structure are disposed between two of the plurality of first contact structures. Each of the first contact structures includes a first liner and a first conductive layer surrounding by the first liner.

In another embodiment of the present disclosure, a method for preparing a semiconductor device is provided. The method includes: forming a source/drain structure over a semiconductor substrate; forming a dielectric layer over the source/drain structure; forming a plurality of first contact structures penetrating through the dielectric layer and the source/drain structure; and forming a second contact structure between two of the plurality of first contact structures, wherein the second contact structure is formed over the source/drain structure. The step of forming the plurality of first contact structures penetrating through the dielectric layer and the source/drain structure includes: performing a first etching process to form a plurality of first openings penetrating through the dielectric layer and the source/drain structure and extending into the semiconductor substrate; forming a first liner covering a sidewall and a bottom surface of each of the first openings; forming a second liner over the first liner; and filling a remaining portion of the first openings with a first conductive layer after the second liner is formed. The first liner and the second liner are made of different materials.

In another embodiment of the present disclosure, a semiconductor device is provided. The semiconductor device includes a semiconductor substrate, a source/drain structure, a dielectric layer, a first contact structure, a polysilicon stack, and a second contact structure. The semiconductor substrate includes an array area and a periphery area. The dielectric layer is disposed over the source/drain structure. The first contact structure is disposed over the periphery area and penetrates through the dielectric layer. The first contact structure includes a first liner and a first conductive layer. The first liner includes tantalum, tantalum nitride, or the combination thereof. The first conductive layer is disposed over the first liner and includes Cu.

In yet another embodiment of the present disclosure, a method for preparing a semiconductor device is provided. The method includes: forming a source/drain structure over a semiconductor substrate, wherein the semiconductor substrate comprises an array area and a periphery area; forming a dielectric layer over the source/drain structure; forming a first contact structure in the periphery area, penetrating through the dielectric layer; forming a polysilicon stack in the array area and over the source/drain structure; and forming a second contact structure over the polysilicon stack. The step of forming the first contact structure in the periphery area, penetrating through the dielectric layer includes: performing a first etching process to form a first opening penetrating through the dielectric layer; forming a first liner covering a sidewall and a bottom surface of the first opening; forming a second liner over the first liner, wherein the first liner and the second liner are made of different materials; and filling a remaining portion of the first opening with a first conductive layer after the second liner is formed.

The embodiments of the present disclosure have some advantageous features. In some embodiments, by forming a polysilicon stack between the source/drain structure and the conductive structure, the contact resistance may be reduced, and the device performance may be improved. In some embodiments, by forming a conductive contact having a barrier layer with different thicknesses, a conductive layer formed over the barrier layer can be void-free, and the device performance may be enhanced.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a source/drain structure disposed over a semiconductor substrate;
a dielectric layer disposed over the source/drain structure;
a plurality of first contact structures, penetrating through the dielectric layer and the source/drain structure;
a polysilicon stack; and
a second contact structure, disposed over the polysilicon stack,
wherein the polysilicon stack and the second contact structure are disposed between two of the plurality of first contact structures,
wherein each of the plurality of first contact structures comprises:
a first liner; and
a first conductive layer, surrounding by the first liner.

2. The semiconductor device of claim 1, wherein each of the plurality of first contact structures further comprises:
a second liner, disposed between the first liner and the first conductive layer.

3. The semiconductor device of claim 2, wherein the second liner includes CuMn.

4. The semiconductor device of claim 1, wherein the first liner includes tantalum, tantalum nitride, or the combination thereof, and the first conductive layer includes Cu.

5. The semiconductor device of claim 1, wherein the plurality of first contact structures extend into the semiconductor substrate.

6. The semiconductor device of claim 1, wherein the second contact structure comprises:
a barrier layer, including titanium, titanium nitride, or the combination thereof; and
a second conductive layer, including tungsten, wherein the second conductive layer is surrounded by the barrier layer.

7. The semiconductor device of claim 6, wherein the barrier layer has a lower portion surrounded by the polysilicon stack.

8. The semiconductor device of claim 1, wherein the source/drain structure comprises:
an epitaxial layer, in contact with the semiconductor substrate; and
a silicide layer disposed between the epitaxial layer and the dielectric layer.

9. The semiconductor device of claim 8, wherein the silicide layer includes cobalt silicide.

10. The semiconductor device of claim 1, wherein the polysilicon stack comprises:
a first polysilicon layer; and
a second polysilicon layer, disposed over the first polysilicon layer, wherein a dopant concentration of the second polysilicon layer is different from a dopant concentration of the first polysilicon layer.

11. The semiconductor device of claim 10, wherein the first polysilicon layer is undoped, and the second polysilicon layer is doped.

12. The semiconductor device of claim 10, wherein the polysilicon stack further comprises:
a third polysilicon layer disposed over the second polysilicon layer, wherein the third polysilicon layer is undoped; and
a fourth polysilicon layer disposed over the third polysilicon layer, wherein the fourth polysilicon layer is doped.

13. The semiconductor device of claim 10, wherein the second polysilicon layer is separated from the dielectric layer by the first polysilicon layer.

14. The semiconductor device of claim 1, wherein the semiconductor device is a part of a dynamic random access memory, and the plurality of first contact structures and the second contact structure are disposed in an array area of the semiconductor device.
